(19) United States
(12) Patent Application Publication
(10) Pub. No.: US 2006/0007661 A1
(43) Pub. Date: Jan. 12, 2006

(54) Circuit board

(75) Inventor: Kenji Iketaki, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 10/976,839

(22) Filed: Nov. 1, 2004

(30) Foreign Application Priority Data
Jul. 8, 2004 (JP) 2004-201717

(51) Int. Cl. H05K 7/20

(52) U.S. Cl. 361/719

(57) ABSTRACT

A circuit board includes a substrate having a pair of pads at mutually opposite positions of a front surface and a rear surface of the substrate; a circuit element having a heat dissipation part which is soldered to one of the pair of pads; and a heat transfer section which pierces through the substrate in a thickness direction, and both ends of which are soldered to the pair of pads respectively, wherein at least a part of the heat transfer section has a solid structure which prevents air from passing through between the front surface and the rear surface.

### BACKGROUND OF THE INVENTION

1. Field of the Invention

The present invention relates to a circuit board having a substrate and a circuit element mounted on this substrate.

2. Description of the Related Art

Along the increased sophistication of a circuit element, a heat dissipation value of the circuit element also increases. As a technique of cooling the circuit element, a metal heat dissipation pad (i.e., a slug) is provided on a portion (i.e., a rear surface) of the circuit element facing the substrate, and this heat dissipation slug is soldered to the metal pad disposed on the substrate, thereby releasing the heat from the circuit element.

FIG. 1 is a cross-sectional diagram of a circuit board to which a heat dissipation slug of a semiconductor element and a pad of a substrate are soldered.

A circuit board 1 shown in FIG. 1 has a semiconductor element 10 and a substrate 20. The semiconductor element 10 is covered with a package 11 which has leads 12 connected to the package 11 by wire bonding. A metal heat dissipation slug 13 is provided on the semiconductor element 10 at a portion facing the substrate. The substrate 20 shown in FIG. 1 has metal pads disposed on a mounting surface 20a on which the semiconductor element 10 is mounted. A conductive layer 201 is provided between the mounting surface 20a and a rear surface 20b opposite to the mounting surface 20a. The heat dissipation slug 13 of the semiconductor element 10 shown in FIG. 1 is connected to a pad (hereinafter referred to as a heat dissipation pad 21) of the substrate 20 with solder 30 (refer to Japanese Patent Application Laid-open (JP-A) No. 10-79562, for example). The lead 12 of the semiconductor element 10 is also connected to a pad (hereinafter referred to as an electric connection pad 22) of the substrate 20 with solder. Through-holes 202 that pierce through the substrate 20 are connected to the heat dissipation pad 21. The inner surface of each through-hole 202 is coated with a conductive material, and the through-hole 202 is brought into contact with the conductive layer 201. Therefore, heat of the semiconductor element 10 is dissipated from the heat dissipation pad 21 and the through-holes 202 to the mounting surface 20a and the inside of the substrate 20. At the same time, the heat is dissipated to the conductive layer 201 via the through-holes 202.

However, as shown in FIG. 1, at the time of connecting the heat dissipation slug 13 to the heat dissipation pad 21 with solder, the molten solder 30 flows into the through-holes 202 shown at the left of the solder 30. The entered solder 30 flows out and swells on the rear surface 20b. When the solder 30 that flows and swells on the rear surface 20b is solidified, this constrains the mounting of elements onto the rear surface, causing problems. When the circuit board 1 is disposed on a limited space, the solder reaching the rear surface 20b interferes with other parts, causing problems as well.

When a circuit board is mounted with a CPU (Central Processing Unit) having an extremely high heat dissipation value, or when a circuit board is mounted with many circuit elements requiring heat dissipation, the conventional technique shown in FIG. 1 cannot manage a rise (or a saturation) in a temperature of the substrate 20, which results in reduced performance of cooling the circuit elements.

To overcome these problems, a technique of obtaining high cooling performance based on a provision of a heat sink on the rear surface 20b of the substrate 20 is proposed (refer to JP-A 11-33074, for example). According to the technique described in JP-A 11-33074, pins that pierce through the substrate are connected to the CPU. The pins transmit the heat of the CPU to the heat sink disposed on the surface opposite to the surface on the CPU is mounted.

According to the technique described in JP-A 11-33074, however, the pins that pierce through the substrate are connected to the CPU with an adhesive. Therefore, a connection portion between the CPU and the pins, that is, a portion of the adhesive, has poor heat conductivity and poor heat dissipation. Consequently, despite the provision of the heat sink, the cooling effect is little improved. The coating of an adhesive also becomes a trouble in the manufacturing process.

### SUMMARY OF THE INVENTION

The present invention has been made in view of the above circumstances, and provides a circuit board having a satisfactory characteristic of cooling a circuit element, without a constraint of mounting the circuit element on the rear surface of the substrate, without an interference with other parts, and without a trouble in the manufacturing process.

According to the present invention, a circuit board includes:
a substrate having a pair of pads at mutually opposite positions of a front surface and a rear surface of the substrate;
a circuit element having a heat dissipation part which is soldered to one of the pair of pads; and
a heat transfer section which pierces through the substrate in a thickness direction, and both ends of which are soldered to the pair of pads respectively, wherein
at least a part of the heat transfer section has a solid structure which prevents air from passing through between the front surface and the rear surface.

According to the circuit board of the present invention, general pads are disposed on the substrate to dissipate heat from the circuit element. Therefore, this has no trouble in the manufacturing process. Because the connection part which transfers heat is soldered, this part has excellent heat conductivity and excellent heat dissipation, thereby satisfactorily cooling the circuit element. Because at least a part of the heat transfer section has the solid structure, the solid structure stops molten solder, and prevents the solder from flowing out and swelling on the surface opposite to the surface on which the circuit element is mounted. As a result, there are no such problems as a constraint of a mounting on the substrate rear surface or an interference with other parts.

The whole heat transfer section can have the solid structure.

According to the circuit board of the present invention, the substrate can have a conductive layer that extends in a direction orthogonal with a thickness direction, inside the substrate.

With the conductive layer kept in contact with the heat transfer section, heat can be released from the circuit element to the conductive layer, thereby increasing heat dissipation effect. When the temperature of the substrate is too high, the conductive layer can have an extended structure by keeping away from the heat transfer section. With this arrangement, a rise in the temperature of the substrate can be suppressed.

According to the circuit board of the present invention, preferably plural heat transfer sections are disposed on the pair of pads.

The plural heat transfer sections can uniformly transfer heat from the circuit element.

According to the circuit board of the present invention, preferably the heat transfer section has a head embedded in one of the pair of pads, at one end in the thickness direction, and has an end part embedded in the other pad at the other end, the head being larger than the other end.

With the above arrangement, the area of the heat transfer section connected to the pads increases, and heat transfer of the pads and the heat transfer section becomes satisfactory.

According to the circuit board of the present invention, preferably a soldered part includes one simple substance selected from a Bismuth simple substance, an Indium simple substance, and a Zinc simple substance.

According to the circuit board of the present invention, the pair of pads are connected to transfer heat, and heat added to one pad is dissipated by the other pad. Because of the necessity of soldering the pads at a high temperature, there is a risk of adding temperature to the circuit element in excess of a heat-resistant temperature of the circuit element. A portion of a soldered member (i.e., the pads, the heat transfer section, and the heat dissipation part) that is brought into contact with the solder is covered with one simple substance selected from the Bismuth simple substance, the Indium simple substance, and the Zinc simple substance. With this arrangement, a melting temperature of the solder can be lowered, and the adding of a temperature to the circuit element in excess of a heat-resistant temperature of the circuit element can be prevented. Therefore, the soldered part includes one simple substance selected from the Bismuth simple substance, the Indium simple substance, and the Zinc simple substance.

According to the circuit board of the present invention, the heat transfer section has a cylinder having an opening at a protrusion end that protrudes in the thickness direction from a first pad out of the pair of pads, the first pad being different from a second pad of which heat dissipation part is soldered.

The heat transfer section can have a heat dissipation member that is fixed to the internal peripheral surface of the cylinder, and has a larger capacity than that of the first pad to dissipate heat transferred from the heat transfer section, at the side where the first pad is provided.

According to the above structure, the use of the cylinder makes it possible to easily dispose the heat dissipation member on the substrate, thereby increasing heat dissipation using the heat dissipation member.

According to the present invention, a circuit substrate with a satisfactory characteristic of cooling a circuit element can be obtained, without troubles of a constraint of mounting on the rear side of the substrate, an interference with other parts, and troublesome work in the manufacturing process.

### BRIEF DESCRIPTION OF THE DRAWINGS

FIG. 1 is a cross-sectional diagram of a circuit board to which a heat dissipation slug of a semiconductor element and a pad of a substrate are soldered;

FIG. 2 is a cross-sectional diagram of a circuit board according to a first embodiment of the present invention;

FIG. 3 is a cross-sectional diagram of a circuit board according to a second embodiment of the present invention;

FIG. 4 is a cross-sectional diagram of a circuit board according to a third embodiment of the present invention; and

FIG. 5 is a perspective diagram of a heat transfer section that is provided on the circuit board shown in FIG. 4.

### DETAILED DESCRIPTION OF THE INVENTION

Embodiments of the present invention are explained below with reference to the drawings.

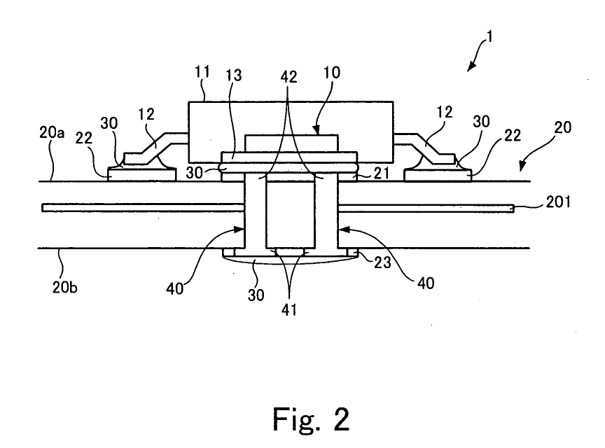

FIG. 2 is a cross-sectional diagram of a circuit board according to a first embodiment of the present invention.

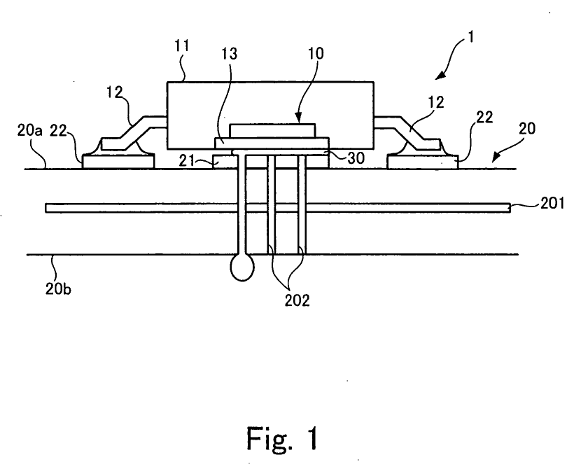

In the following explanation, constituent elements having the same functions as those of the constituent elements shown in FIG. 1 are attached with like reference numerals. (the same applies hereinafter)

The circuit board 1 shown in FIG. 2 also has the semiconductor element 10 covered with the package 11, and the substrate, like the circuit board shown in FIG. 1. The semiconductor element 10 has plural leads 12, and the metal heat dissipation slug 13. The heat dissipation slug 13 shown in FIG. 2 is coated with a low melting-point material containing Bi (bismuth).

On the other hand, a pair of metal pads are provided at mutually opposite positions of a front surface and a rear surface of the substrate 20 shown in FIG. 2. These pads are also coated with a low melting-point material containing Bi of the front and rear surfaces, a surface on which the semiconductor element 10 is mounted is called the mounting surface 20a, and the opposite surface is called the rear surface 20b. Out of the pair of pads, the pad (i.e., the heat dissipation pad 21) disposed on the mounting surface 20a is connected to the heat dissipation slug 13 of the semiconductor element 10 with the solder 30. Out of the pair of pads, the pad disposed on the rear surface 20b is called a heat dissipation rear-surface pad 23. Plural metal pads are provided on the mounting surface 20a, regardless of the opposed relationship with the rear surface 20b. The plural leads 12 of the semiconductor element 10 are connected to these pads (i.e., metal connection pads 22) with the solder 30. The substrate 20 shown in FIG. 2 has the conductive layer 201 that extends in a direction orthogonal with a thickness direction, inside the substrate 20.

The circuit board 1 shown in FIG. 2 has plural heat transfer sections 40. Plural through-holes, of which inner surface is coated with a conductive material, are provided on the substrate 20 shown in FIG. 2 to pierce through the substrate 20 in a thickness direction and connect between the heat dissipation pad 21 and the heat dissipation rear-surface pad 23. The heat transfer sections 40 are accommodated in the through-holes, and both ends of the heat transfer sections 40 are soldered to the heat dissipation pad 21 and the heat dissipation rear-surface pad 23 respectively. In other words, the heat transfer sections 40 pierce through the substrate 20 in the thickness direction, and are soldered to the heat dissipation pad 21 and the heat dissipation rear-surface pad 23 respectively. The heat transfer sections 40 are brought into contact with the conductive layer 201 inside the substrate. Therefore, heat of the semiconductor element 10 is transferred from the heat dissipation slug 13 to the heat dissipation pad 21. The heat is further transferred to the conductive layer 201 and to the heat dissipation rear-surface pad 23, via the heat transfer sections 40. As a result, the heat of the semiconductor element 10 is dissipated by the heat dissipation pad 21 and the heat dissipation rear-surface pad 23, and is also released to the conductive layer 201. According to the circuit board 1 shown in FIG. 2, all the connection parts that transfer heat are soldered. Therefore, these connection parts achieve excellent heat conduction and heat dissipation, thereby cooling the semiconductor element 10 satisfactorily. Because general pads are disposed on the substrate 20 to dissipate heat from the semiconductor element 10, no troublesome work is involved in the manufacturing process. Because plural heat transfer sections 40 are disposed on the pair of pads 21 and 23, heat is transferred uniformly from the semiconductor element 10.

Each heat transfer section 40 has a head 41 and an end part 42, and seals air between the mounting surface 20a and the rear surface 20b. In other words, each heat transfer section 40 shown in FIG. 2 has a solid structure in total. A portion excluding the head 41 is a cylinder, and one end of the cylinder forms the end part 42. The head 41 has a larger diameter than that of the cylinder, and is positioned opposite to the end. The head 41 of each heat transfer section 40 shown in FIG. 2 is soldered to the heat dissipation rear-surface pad 23 in a state of being embedded in the heat dissipation rear-surface pad 23. The end part 42 is soldered to the heat dissipation pad 21 in a state of being embedded in the heat dissipation pad 21. As shown in FIG. 2, the solder 30 is solidified to cover the total surface of the heat dissipation rear-surface pad 23 in which the head 41 is embedded. The solder 30 is also solidified to cover the total surface of the heat dissipation pad 21 between the heat dissipation pad 21 in which the end part 42 is embedded and the heat transfer slug 13 of the semiconductor element 10. Therefore, both the head 41 and the end part 42 of each heat transfer section 40 secure a sufficient area to have contact with the pads. Consequently, heat transfer between the pads and each heat transfer sections 40 is very satisfactory. Because each heat transfer section 40 has a solid structure in total, this structure prevents the molten solder, before solidification between the heat dissipation pad 21 and the heat dissipation slug 13, from flowing out to the rear surface 20b. Each heat transfer section 40 can omit the head 41.

Because the heat dissipation slag 13, the heat dissipation pad 21, and the heat dissipation rear-surface pad 23 are all coated with a low melting-point material containing Bi, the soldered portions also contain the Bismuth simple substance. According to the circuit board 1 shown in FIG. 2, the pair of pads including the heat dissipation pad 21 and the heat dissipation rear-surface pad 23 are connected together to transfer heat. Heat added to one pad is dissipated by the other pad. While these pads require a soldering at a high temperature, the low melting-point material coated on these pads allows the solder to be melted at a temperature about the same as that of soldering the electric connection pad 22. The low melting-point material can be covered according to a method different from the coating (such as a dropping with a dispenser or a partial printing, for example).

A circuit board according to a second embodiment of the present invention is explained below. A duplicate explanation of the first embodiment is omitted, and characteristic parts of the second embodiment are mainly explained.

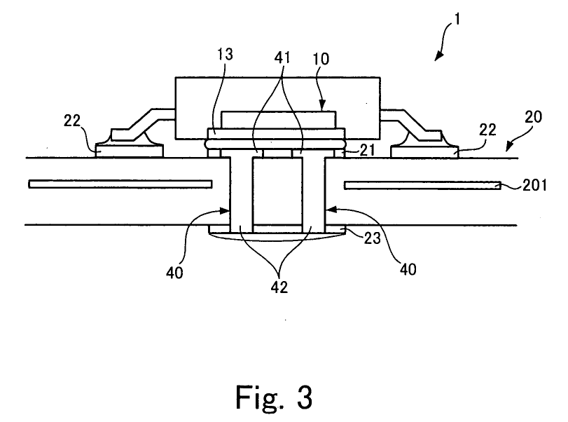

FIG. 3 is a cross-sectional diagram of a circuit board according to the second embodiment of the present invention.

The circuit board 1 shown in FIG. 3 also has plural heat transfer sections 40. However, the head 41 of each heat transfer section 40 shown in FIG. 3 is soldered to the heat dissipation pad 21 in a state of being embedded in the heat dissipation pad 21, and the end part 42 is soldered to the heat dissipation rear-surface pad 23 in a state of being embedded in the heat dissipation rear-surface pad 23. Each heat transfer section 40 is accommodated in a through-hole that is mechanically formed on the substrate 20. A low melting-point material is not coated on any one of the heat dissipation slag 13, the heat dissipation pad 21, and the heat dissipation rear-surface pad 23 shown in FIG. 3. All the heads 41 and the ends 42 of the heat transfer sections 40 are coated with a low melting-point material containing Bi respectively. Therefore, the solder is melted at a temperature about the same as that of soldering the electric connection pad 22. The heat transfer sections 40 shown in FIG. 3 are not brought into contact with the conductive layer 201 of the substrate 20. The semiconductor element 10 shown in FIG. 3 is a CPU (Central Processing Unit) having a large heat dissipation value. When the heat transfer sections 40 are brought into contact with the conductive layer 201, the temperature of the substrate 20 becomes too high. Therefore, the heat transfer sections 40 are intentionally separated from the conductive layer 201 in this example.

A circuit board according to a third embodiment of the present invention is explained below. A duplicate explanation of the first and the second embodiments is omitted, and characteristic parts of the third embodiment are mainly explained.

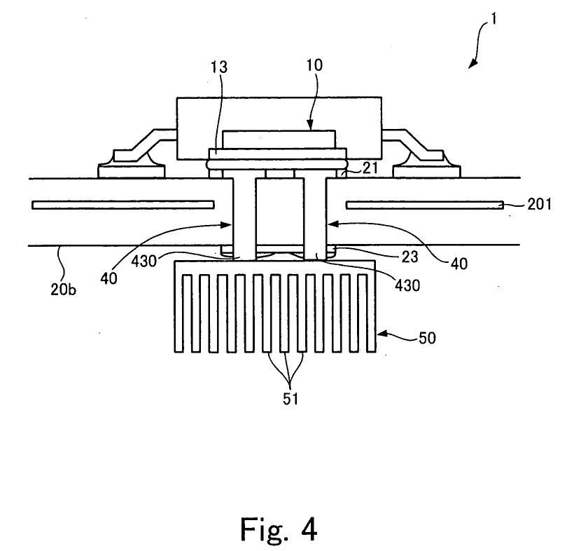

FIG. 4 is a cross-sectional diagram of a circuit board according to the third embodiment of the present invention.

The semiconductor element 10 shown in FIG. 4 is a CPU having an extremely high heat dissipation value. According to the circuit board 1 shown in FIG. 4, the heat transfer sections 40 are also separated from the conductive layer 201 to avoid a rise in the temperature of the substrate, like the circuit board shown in FIG. 3. The circuit board 1 shown in FIG. 4 has a heat sink 50 disposed on the rear surface 20b. The heat sink 50 has plural fins 51 having a larger capacity than that of the heat dissipation rear-surface pad 23. Each heat transfer section 40 shown in FIG. 4 has a tube 430 that stretches from the heat dissipation rear-surface pad 23 in a thickness direction of the substrate 20. The peripheral surface of the tube 430 is soldered to the heat dissipation rear-surface pad 23.

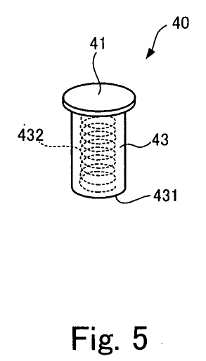

FIG. 5 is a perspective diagram of a heat transfer section that is provided on the circuit board shown in FIG. 4.

The heat transfer section 40 shown in FIG. 4 has a disk-shaped head 41 and a cylinder 43. The head 41 is provided to seal an opening at one end of the cylinder 43. An opening 431 at the other end of the cylinder 43 is kept open. Therefore, the head 41 of the heat transfer section 40 shown in FIG. 5 has a solid structure, and accordingly, a part of the heat transfer section 40 has a solid structure. A thread groove 432 is provided on the internal peripheral surface of the cylinder 43, from the opening 431 toward the head 41. The end part of the opening 431 of the cylinder 43 is equivalent to the tube 430 shown in FIG. 4.

The heat sink 50 shown in FIG. 5 has an insertion section that is inserted into the opening of the heat transfer section 40 shown in FIG. 5. The insertion section has a thread groove that meshes with the thread groove 432 provided on the internal peripheral surface of the cylinder 43. The heat sink 50 shown in FIG. 4 is meshed with the internal peripheral surface of the cylinder of each heat transfer section 40. The heat sink can be easily mounted. Heat is transferred from the heat transfer sections 40 to the mounted heat sink 50. According to the circuit board 1 shown in FIG. 4, heat of the semiconductor element 10 is transferred from the heat dissipation slug 13 to the heat dissipation pad 21. Further, the heat is transferred to the heat dissipation rear-surface pad 23 via the heat transfer sections 40, and is efficiently dissipated from the heat sink 50. In fixing the heat sink 50 to the internal peripheral surface of the cylinder of each heat transfer section 40, meshing is not the only method. Other method such as pushing can be used according to various mechanical fastening methods.

What is claimed is:

1. A circuit board comprising:
a substrate having a pair of pads at mutually opposite positions of a front surface and a rear surface of the substrate;
a circuit element having a heat dissipation part which is soldered to one of the pair of pads; and
a heat transfer section which pierces through the substrate in a thickness direction, and both ends of which are soldered to the pair of pads respectively, wherein
at least a part of the heat transfer section has a solid structure which prevents air from passing through between the front surface and the rear surface.

2. The circuit board according to claim 1, wherein
the substrate has a conductive layer that extends in a direction orthogonal with a thickness direction, inside the substrate.

3. The circuit board according to claim 1, wherein
a plurality of the heat transfer sections are disposed on the pair of pads.

4. The circuit board according to claim 1, wherein
the whole heat transfer section has the solid structure.

5. The circuit board according to claim 1, wherein
the heat transfer section has a head embedded in one of the pair of pads, at one end in the thickness direction, and has an end part embedded in the other pad at the other end, the head being larger than the other end.

6. The circuit board according to claim 1, wherein
a soldered part includes one simple substance selected from a Bismuth simple substance, an Indium simple substance, and a Zinc simple substance.

7. The circuit board according to claim 1, wherein
the heat transfer section has a cylinder having an opening at a protrusion end that protrudes in the thickness direction from a first pad out of the pair of pads, the first pad being different from a second pad of which heat dissipation part is soldered, and
has a heat dissipation member that is fixed to the internal peripheral surface of the cylinder, and has a larger capacity than that of the first pad to dissipate heat transferred from the heat transfer section, at the side where the first pad is provided.
